(19) United States
(12) Patent Application Publication
(10) Pub. No.: US 2026/0197945 A1
(43) Pub. Date: Jul. 9, 2026

(54) PATTERN RECOGNITION SYSTEM AND METHOD FOR DIGITAL PRINTED CIRCUIT BOARD ASSEMBLY

(71) Applicants: PRISMA ELECTRONICS S.A., ALEXANDROUPOLI (GR); NATIONAL TECHNICAL UNIVERSITY OF ATHENS, ATHENS (GR)

(72) Inventors: CHRISTOS GIORDAMLIS, ALEXANDROUPOLI (GR); IOANNA ZERGIOTI, PAPAGOS (GR); MARINA MAKRYGIANNI, CHALANDRI (GR); FILIMON ZACHARATOS, ATHENS (GR); IOANNIS THEODORAKOS, GERAKAS (GR)

(73) Assignees: PRISMA ELECTRONICS S.A., ALEXANDROUPOLI (GR); NATIONAL TECHNICAL UNIVERSITY OF ATHENS, ATHENS (GR)

(21) Appl. No.: 19/134,500

(22) PCT Filed: Nov. 29, 2023
(86) PCT No.: PCT/EP2023/083610

§ 371 Date: May 30, 2025

(30) Foreign Application Priority Data
Nov. 30, 2022 (GR) 20220100986

(51) Int. Cl. H05K 3/00; B23K 1/00; B23K 3/08; B23K 101/42; H05K 3/3465

(52) U.S. Cl. CPC H05K 3/0008; B23K 1/0016; B23K 3/08; H05K 3/3465; B23K 2101/42

(57) ABSTRACT

The invention relates to a method for pattern recognition to assemble printed circuit boards by digital printing and a system for implementing the method. In the method, pattern recognition techniques are applied to extract information from imaging of the printed circuit board, thereby enabling automated printing of a targeted object on the board. The method comprises digital printing of a material that is uniformly coated on a transparent donor substrate and positioned in parallel to a receiver substrate. A laser pulse irradiates the donor substrate, resulting in detachment and transfer of a portion of the material onto the receiver substrate. The method enables reduction of overall processing time while achieving high alignment accuracy and high printing resolution.

### RELATED APPLICATIONS

This application is a national stage application under 35 U.S.C. § 371 of International Patent Application No. PCT/EP2023/083610, filed Nov. 29, 2023 and published as WO 2024/11603 A1 on Jun. 6, 2024, which claims priority to Greek Patent Application No. 20220100986, filed Nov. 30, 2022, which are all hereby incorporated by reference in their entirety.

### BACKGROUND

### Field

The invention refers to the field of electricity and more specifically to the field of printed circuits, compartments or components of electrical and electronic devices and the manufacturing of assembled parts. It further refers to the field of physics and measuring instruments in general and in particular to the field of measurements and tests. Even more specifically, it refers to the field of research and analysis of materials, determining their physical or chemical properties. It also refers to the fields of radiation analysis of materials, mass spectrometry, and the determination of the presence, the laser intensity, the fluence, the energy, or the particles. It specifically refers to a pattern recognition system and method for the assembly of printed circuit boards by digital printing.

### Background Information

The method and pattern recognition system disclosed in the present invention for assembling printed circuit boards by digital printing, have not been disclosed in the prior art.

Surface Mount Technology (SMT—Surface-Mount Technology) is a technology for assembling and bonding SMD (Surface Mounted Device) components, such as resistors, capacitors, transistors, integrated circuits on a printed circuit board (PCB—Printed Circuit Board), through a process of annealing the adhesive material (reflow soldering). SMD components are also referred to as chip components.

By reducing the dimensions of the components, the SMT technology presents some limitations, such as indicative and non-limiting, listed below. Stencil printing used to deposit solder paste is responsible for most PCB assembly defects. Parameters that limit assembly are variations in printed adhesive paste volumes, as well as misalignment. In addition, using mask printing, the processing of small-sized components for high assembly density (ultra-fine pitch components) is quite limited, while it is not possible to process ultra-thin components (thickness <50 μm) attached to flexible substrates. Furthermore, there is a limitation in dimensions, in cases below 200 μm, the assembly of parts with a significant height mismatch is not possible, as well as edge coupling or vertical connection. Another existing disadvantage is that there is no visual control in real time of the printing of the adhesive paste on the PCB board.

Finally, SMT PCB prototyping or low-volume production is expensive and often unprofitable.

### SUMMARY

It is thus an objective of the present invention to reduce and improve the above disadvantages described in the current state of the art and to provide a system and method for assembling PCB boards by digital printing.

A further objective of the present invention is to offer partial automation of the targeting/printing process with high accuracy and speed, by finding special fiducials, using a high-resolution camera and software with pattern recognition algorithms. It is a further objective of the present invention to help eliminate the need for precision in the physical placement of the PCB board in terms of its orientation during printing. These and other objectives, features and advantages of the invention will become apparent in the following detailed description.

In particular, it is disclosed a method for the assembly of printed circuit boards by digital printing, more in particular a pattern recognition method for the assembly of printed circuit boards by digital printing, where a printed circuit board is fixed on a target platform (board) and a laser source is adjusted with respect to a target platform. Pictures are captured via an imaging setup, of the printed circuit board to be assembled. The coordinates of the shape and areas of interest on the printed circuit board where the solder paste will be deposited, are extracted. Special markers are located and identified on the captured pictures of the board, through pattern recognition methods, for the solder paste deposition. The position and orientation of the physical object to be targeted on the platform, such as the circuit board, is identified. A donor substrate is placed and aligned, and the donor/donor substrate is coated with a solder paste layer. Digital solder deposition is achieved via laser printing, the printed circuit board to be assembled is placed in a component placement machine, the parts are deposited in predetermined positions and thermal annealing takes place for the final bonding.

The described method has the following advantages:
1) It combines pattern recognition and laser printing technology for assembling Printed Circuit Boards (PCB), adding substantial value in terms of industrial exploitation.
2) It offers a targeting/printing process with high accuracy and speed, by finding special fiducials, using a high-resolution camera and software with pattern recognition algorithms.
3) It eliminates the need for precision and broadens the tolerance in regards to the physical placement of the PCB in terms of its orientation during printing.

Preferably, for the identification of the special markers, it is confirmed that elements in a captured picture, that are possible shapes to be searched for, are in a picture with a black background and are of a different color, wherein in case the background of the picture is not black, the picture is converted accordingly. It is understood that the captured picture comprises elements that are possible shapes to be searched for identifying the special markers. The elements may comprise the special markers and other shapes. Thus, for identifying the special markers, it searched for elements in the captured picture. To this end, it is preferably confirmed that the elements are in a picture with a black background and are of a different color than the black background, wherein in case the background of the picture is not black, the picture is converted accordingly.

Preferably, the identification of the special, colored markers is done on a black background, whilst in case the background of the picture is not black, the contrast of the picture is enhanced accordingly.

Preferably, the identification of the special markers involves converting the image to black and white, so that the special markers are displayed in white on a black background or vice versa.

Preferably, detected elements in the picture are counted and their number is measured.

Preferably, the set of detected elements is re-processed, in other words all the detected elements are re-processed. During re-processing, each of the detected elements is checked, with shape detection algorithms, to see if any of the detected elements match some type of simple geometric shape. The formulation “shape detection algorithms” may in particular comprise the case where (only) one shape detection algorithm and/or the case more shape detection algorithms is/are used. Simple geometric shapes in particular comprise a rectangle, a circle, a square, a triangle a polygon, a parallelogram, a rhombus etc.

Preferably, edge pixels of each detected element are checked to verify whether they meet certain criteria, so that the detected elements are classified into known shapes. The known shapes in particular correspond to the simple geometric shapes mentioned above. It is understood that for each known shape the criteria are different. In other words, the criteria depend on the corresponding shape for which it is checked whether the detected element meets can be classified into this shape. For example, for a detect element to be classified into the shape of a circle, the criteria may comprise checking whether the edge pixels have the same distance from a point (the center of the circle).

Preferably, the set of known shapes detected is subjected to a final check as to whether each of them belongs to the circle class. In other words, all detected known shapes are each subjected to a final check as to whether they belong to the circle class, namely if each detected known shape is a circle or not.

Preferably, all the circles are presented in order to decide whether some or all of them are accepted by a user. In other words, all the circles are preferably presented to a user for deciding whether they are accepted or not.

Preferably, three special markers are identified.

It is checked if a required number of special markers is identified, in particular before the extraction of the coordinates of the shape and areas of interest on the printed circuit board where the solder paste will be deposited. The required number is preferably three special markers.

For the extraction of the coordinates of the shape and areas of interest on the printed circuit board where the solder paste will be deposited, Gerber data of the printed circuit board are preferably converted into printing data. Preferably, errors regarding the positions of the points to be printed and the orientation of the shapes to be printed are corrected. According to this advantageous aspect, the converted printing data are corrected before they are used for the printing process.

Within the framework of the present invention, the terms “photograph”, “picture” and “image” may preferably be used interchangeably.

Within the framework of the present invention, the terms “special markers”, “specific markers” and “fiducials” may preferably be used interchangeably.

### BRIEF DESCRIPTION OF THE DRAWINGS

The invention will become apparent to those skilled in the art by reference to the accompanying drawings in which it is illustrated in an illustrative non-limiting manner.

FIG. 1 shows the logic diagram of the pattern recognition method for assembling printed circuit boards by digital printing, in accordance with what is presented in the present invention.

FIG. 2 shows an illustration of the micromachining device of the present invention.

FIG. 3 shows a printed circuit board with special circular objects known as fiducials.

FIG. 4 shows an example of a Gerber file.

FIG. 5 shows fiducials of the printed circuit board detected by the pattern recognition method.

FIG. 6 shows an example of calculations of absolute distances between points (e.g. |x2−x1|) and torsion angles (φ and θ) for detecting the fiducials.

### DETAILED DESCRIPTION

Referring now to the accompanying drawings, we will describe exemplary embodiments of both the method and the pattern recognition system for digitally printed circuit board assembly used in said method.

Laser printing is a direct printing technique with the possibility of depositing materials in liquid or solid phase. The basic steps of the technique are summarized as follows: (i) the material to be printed is uniformly coated on a transparent, with respect to the laser radiation wavelength, donor substrate and placed in parallel, in close proximity to an acceptor substrate. (ii) A laser pulse of a specific energy irradiates the transparent substrate/material to be printed resulting in the detachment and printing of part of the material on the receiver. The laser printing technique offers the possibility to print small volume structures, with fast printing speed and high accuracy in terms of quantity control. Laser printing technology is a flexible, high-quality, efficient and cost-effective process for interconnecting small and very small electronic components with a resolution of less than 100 μm, in electronic applications. In particular, it provides the possibility to print a small amount of adhesive paste on the PCB board with a high printing rate (>10,000 contacts per second) and high precision for quantity control.

Direct printing of the solder paste onto the PCB board and the subsequent interconnection of electronic components, thus skipping the expensive step of placing solder paste beads at the wafer-level, simplifies and reduces the cost of the assembly process. In addition, the additive nature of the process allows for one-step fabrication, thereby limiting the consumption and disposal of functional materials. By using this technique, the steps in the industrial IC assembly process are significantly reduced, as the mask design and fabrication step is bypassed.

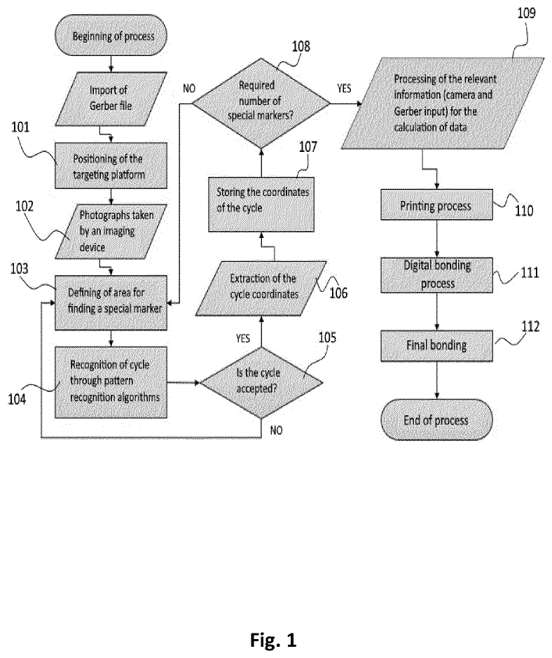

The steps followed to implement the method initially require fixing the printed circuit board (PCB) to a predetermined point on the system's target platform and physically constraining the board with appropriately shaped pins, which demarcate its outer limit positions. Using micromechanics, the position of the targeting platform is adjusted relative to the laser source (step 101), FIG. 1. Photographs of the printed circuit board to be assembled are then taken using an imaging device (step 102). The printed circuit board assembly data (Gerber file of the PCB) is entered into system control software. The purpose of the input is to extract the information regarding the coordinates, shape and area of the areas of the printed circuit, where adhesive paste will be deposited. After the printed circuit board is fixed in the assembly, its image is taken, through a high-resolution camera, to start the process of detecting and finding the required fiducials, extracting the necessary data and continuing with the printing process.

Recognition and identification of special markers on printed circuit board photographs requires the application of pattern recognition methods based on printed circuit board industry design and manufacturing standards (steps 103-104). To detect and analyze a shape present in an image, the pixels of the image should be checked, as these will be used as the input information for the shape analysis process, based on the relevant algorithms. In the first phase, it should be confirmed that the objects in the image, that are possible shapes to be searched for, are in an image with a black background and are of a different color. In case the depth (background) of the image is not black, the image should be converted accordingly. As the special markers are circular shapes, only the circles (step 104) are be detected in this particular procedure. The idea of the circle detection algorithm is based on the assumption that all edges of the shape have the same distance from its center (ideal circle), which is equal to the radius of the circle.

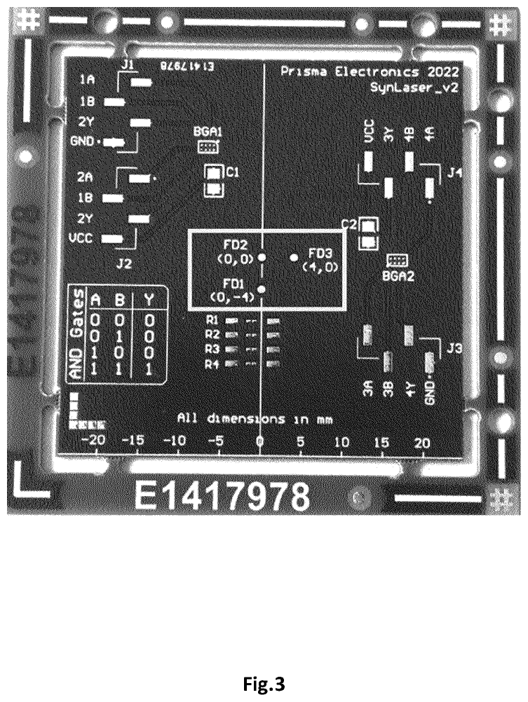

However, it is possible for a circular shape to have some distortion, so some pixels of the image located on the perimeter of the circle are somewhat closer or further away from its center (non-ideal circle). This variation in the distance from the center should not be too large and should be within certain acceptable limits, since if they are too large, then the object under examination is probably not in the shape of a circle. In particular, acceptable limits are preferably considered when a distance from the center is smaller or larger by at most 10%, more preferably by at most 5%, of the radius of the ideal circle. For a given set of pixels of the perimeter of a circle it is easy to estimate its center and radius by finding the bounding rectangle. Once the radius and center of the circle are calculated, then all that is needed is to calculate the distance of the perimeter pixels from the estimated center and check the difference with the estimated radius. Instead of checking each individual distance value for each pixel of the perimeter, one can simply calculate the average distance and then check whether the value falls within a certain range or not. This certain range is preferably the one defined above, namely at most ±10%, more preferably at most ═5%, of the radius of the ideal circle. Ideally each value should tend to zero, which means that all points on the perimeter fit within the estimated circle. Otherwise, a shape distortion level should be allowed, which should depend on its size, allowing a higher distortion level for larger shapes and a lower distortion level for smaller shapes. The above procedures are performed automatically by the relevant software that implements the specific steps of the method. To minimize the time of the overall process, as well as errors, due to the large size of the image and the number of elements in total, and to start the process of finding a special marker, which is required in one of the steps of the method, the user should define a specific area of the image by marking it (step 103). For example, such a specific area is indicated by the rectangle in FIG. 3 which surrounds the fiducial points FD1, FD2, and FD3. So based on the process of detecting and finding circular shapes, the steps performed algorithmically to detect and find the special markers in the region of the received image of a board are as follows:

The identification of the special markers involves converting the image to black and white, so that the special markers, i.e. the circles that are desired to be detected, are displayed in white on a black background or vice versa. Then the detected elements are counted and their number is measured, in order to extract the relevant list. The set of detected elements is re-processed, in which each of them is checked, with shape detection algorithms, to see if any of them match some type of simple geometric shape. Essentially, the edge pixels of each object are checked whether they meet certain criteria, so that the objects are classified into known shapes. The set of known shapes detected is subjected to a final check as to whether each of them belongs to the circle class (step 104). At the end, all the circles are presented in order to decide whether some or all of them are accepted by the user (step 105).

In the next step of the method, the position and orientation of the physical object to be targeted on the platform is recognized and the transformation of the three coordinate systems (step 106) is extracted, at which point the user defines which of the three required special indicators is about, so that the coordinates of its position (step 107) are stored. The circle detection process above is repeated until the required number of three special markers (step 108) is filled. The three systems concern the printed circuit board design, the targeting system, and the actual physical object on the targeting platform (step 109).

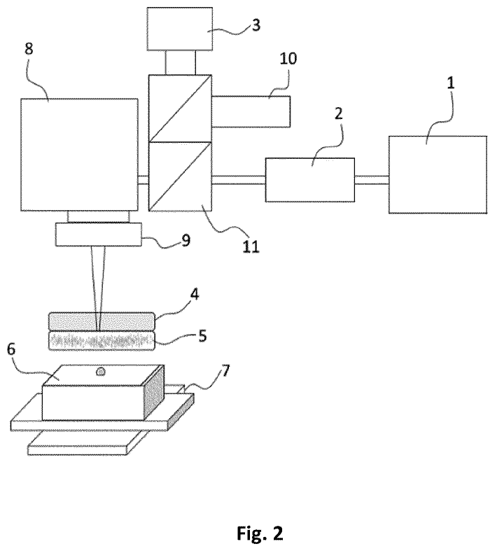

The donor substrate is then positioned and aligned, using the controlled X-Y movement of the system's stepper motors, coating-covering the donor with a thin layer (10-150 μm thick) of adhesive paste (step 110) and the digital bonding process follows, using printing with laser (step 111). The next steps involve placing the printed circuit board to be assembled in a component placement machine and depositing the components in their predetermined positions, followed by placing the printed circuit board to be assembled in a thermal annealing machine for the achievement of the final bonding (step 112). Finally, visual and sample inspections will follow to certify proper operation. The system for pattern recognition for the assembly of printed circuit boards by digital printing, according to the invention, comprises a laser micro-processing station, FIG. 2, that comprises a pulsed laser source 1, a laser scanning system, an optical path 2, comprising optical parts, such as lenses and mirrors, but also a controllable arrangement for the X-Y movement of donor/receiver substrates, via stepper motors. Furthermore, there is a base for the receiver substrate 6, i.e., a PCB board, with maximum indicative dimensions of 100×100 mm². The laser scanning system comprises a two-dimensional galvanometric system 8 and an F-theta 9. The optical path comprises guiding a laser beam through a series of mirrors (11), a two-lens arrangement, to magnify the laser beam to a size determined by the diameter of the entrance hole of the galvanometric system and to parallelize it before entering the two-dimensional galvanometric system and a beam attenuator arrangement. The controllable printing setup includes a transparent carrier 4 coated with solder paste 5, a receiver substrate 6, a stepper motor with movement in the Z direction, and an adjustable XY translation stage configuration 7.

The system also includes an additional imaging setup to visualize in real time the experimental process, comprising a CMOS camera 3, combined with a series of optics, such as an achromatic lens, a dichroic mirror, placed in line with the laser beam propagation axis and illuminating the donor substrate via a LED source 10.

The system is controlled by a computer and a software specifically developed for this process. The software is responsible for configuring the system, controlling the electromechanical parts (stepper motors, galvanometric system) and supervising the solder paste printing process. Achieving μm-level accuracy in identifying and recognizing the location of fiducials on the board with pattern recognition is possible through the use of a high-resolution camera and image processing algorithms from machine learning programming libraries.

In the following, aspects of the invention are described in more detail. Some features of the invention are repeated here for a better understanding of the method.

Given the fact that the laser printing procedure of the system, in assembling and bonding SMD components on a PCB, is targeting components and shapes of very small dimensions (<200 μm), high accuracy and reproducibility are required. The basic problem is that when the user places the PCB on the platform manually, it is not possible to have all the targeted fiducials in the exact correct location that they should be (Example of the fiducials is displayed in FIG. 3). The need for high precision during the placement of the PCB on the system's platform by the user, regarding its location and orientation, is more than critical for a successful outcome.

One of the main benefits of the invention is that it helps eliminate the need for precision in the physical placement of the PCB board in terms of its orientation during printing. To do that, the relevant errors, and deviations in the calculated locations of the points to be laser-printed (i.e., their coordinates on the X-Y level) are calculated and the offsets of these points are corrected.

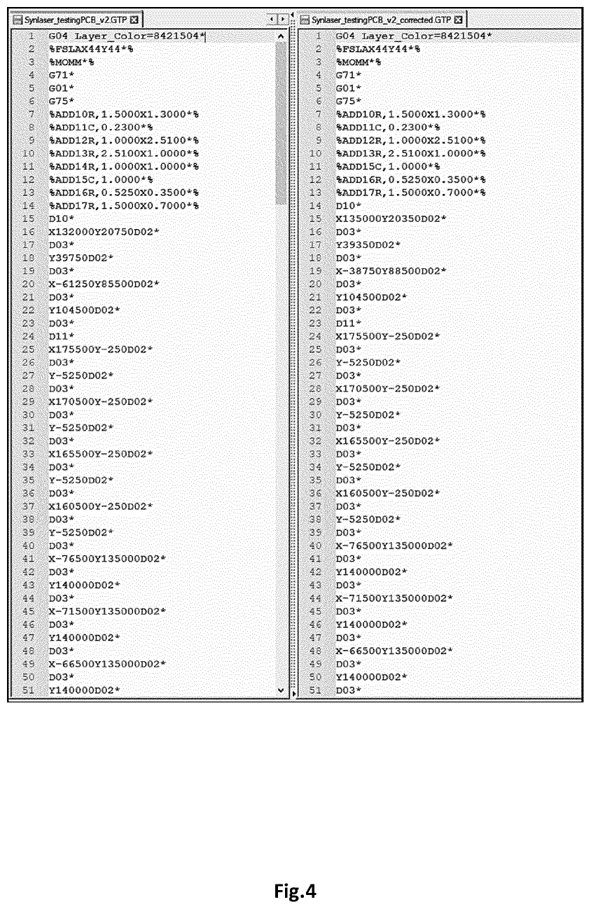

To calculate the coordinates of the printing area, the invention uses the Gerber data of the PCB as a basis for the output of the laser printing procedure. These Gerber data are converted into printing data that can be used specifically by the printing system (imported Gerber file in FIG. 4). The data conversion is implemented via a software library. However, if the converted printing data are used as they are, then the laser printing procedure may not produce the desired outcome, as it is possible that there are errors regarding the positions of the printed points and the orientation of the printed shapes. For the correction of these errors another procedure is preferably followed, so that the offsets of every point to be printed is calculated. This procedure dictates that the system's user locates three special points-objects (the previously mentioned fiducials) on the PCB, via the help of a high-resolution camera. By locating the fiducials, firstly, the exact location of the PCB's center is known, in terms of its coordinates on the X-Y level and in relevance with the center of the galvanometric system 8, and secondly, is it is possible to calculate the orientation and torsion of the PCB, in relevance with its desired location, and thus the deviations between the desired and the actual location for every point to be printed. As the fiducials are circular shapes, only circles are detected during this process. As also presented above, the whole idea of the circle detection algorithm is based on the hypothesis that all the pixels on the edges of the shape have the same distance from its center (ideal circle), which is equal to the radius of the circle. However, it is possible for a circular shape to have some distortion, so that some pixels of the image located on the perimeter of the circle are either closer or further from its center (non-ideal circle). This variation in the distance from the center should not be too large and should be within certain acceptable limits as mentioned above, since if they are too large the object that is examined is probably not circular in shape. For a given set of pixels of the perimeter of a circle it is easy to estimate its center and radius by finding the bounding rectangle. Once the radius and center of the circle are calculated, then all that is required is to calculate the distance of the perimeter pixels from the estimated center and check the difference with the estimated radius. Instead of checking each individual distance value for each pixel of the perimeter, one can simply calculate the average distance and then check whether the value falls within a certain range or not. Ideally, each value should tend to zero, which means that all points on the perimeter fit within the estimated circle. Otherwise, a shape distortion level should be allowed, which should depend on its size, allowing a higher distortion level for larger shapes and a lower distortion level for smaller shapes.

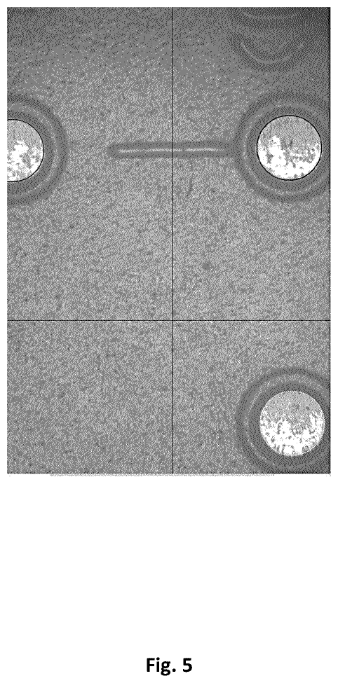

To minimize the time, as well as the errors, of the overall procedure of detecting a fiducial, which is a circle, due to the large size of the image and the number of the detected elements in the image total, the user should start the process by defining a specific area of the image, marking it with the help of the computer's mouse, and choose whether the system should check the marked area for a light circle in dark background, or for a dark circle in light background (FIG. 5). This is preferably done three (3) times, as is the number of the fiducials that need to be detected, before starting the laser printing procedure. It is noted that the only components of the PCB that need to be located via the camera are the fiducials.

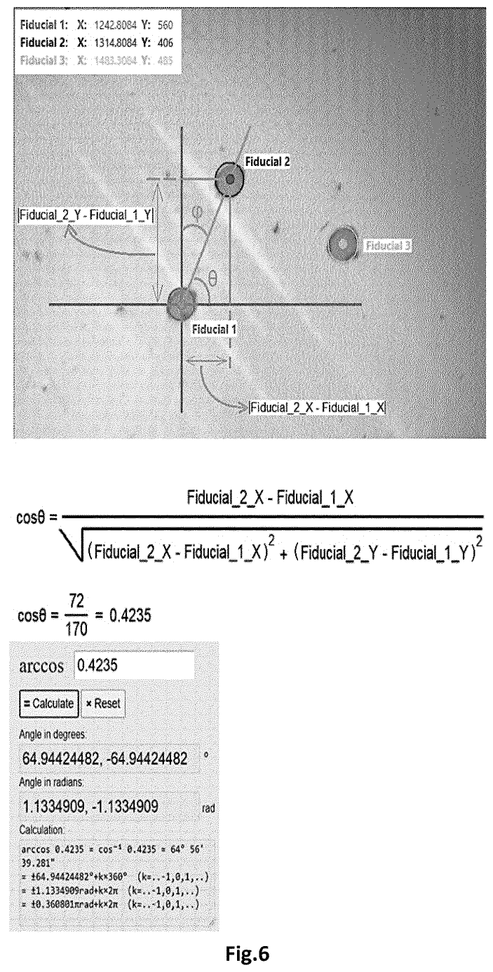

The printing process data that are required to define the laser aiming points derives from calculations that combine the information of the imported Gerber file and the information of the calculated X-Y coordinates of the fiducials that is saved after their detection. With the fiducials coordinates available, the relevant mathematical calculations of the required data (offsets calculations) for the laser printing process can be done, according to basic geometric and trigonometric equations, on how to find the necessary angles and distances, in the case that the board is placed somewhat crooked (FIG. 6). More specifically, with the help of basic mathematical theorems and equations (Pythagorean theorem, trigonometric equation of either the sine or cosine of an acute angle of a right triangle, sum of angles of a triangle equals 180°), the corresponding absolute distances and torsion angles φ and θ can be calculated. Thus, with the data available from these calculations and from the Gerber files data, it is possible to calculate the coordinates of the actual points that are to be targeted, during the laser printing process, with relatively high accuracy, regardless of the orientation and placement of the PCB on the platform by the user.

Considering the above, a procedure of digital printed circuit board (PCB) assembly via the laser printing technique that is assisted by a pattern recognition system, in order to achieve high accuracy and quality in interconnecting electronic components of very small dimensions is provided. More specifically, with the use of the shape recognition system, which is a more specialized case of pattern recognition, the need for manual intervention by the user in the procedure of PCB laser printing, as well as the discrepancies between the desired result and the actual outcome of the laser printing procedure on the circuit board, are minimized. This is accomplished by defining and calculating the exact location and orientation of the board on the X-Y axis level.

It should be noted here that the description of the invention was made with reference to illustrative application examples to which it is not limited. Likewise, any change or modification in terms of shape, dimensions, morphology, materials used and construction and assembly components, as long as they do not constitute a new inventive step and do not contribute to the technical development of what is already known, are considered included in the aims and objectives of the present invention as summarized in the following claims.

The invention can also be described by the following disclosure:
1. Pattern recognition method for the assembly of printed circuit boards by digital printing, where a printed circuit board is fixed on a target board, a laser source is adjusted with respect to the target platform, pictures are captured via an imaging setup, of the printed circuit board to be assembled, the coordinates of the shape and areas of interest on the printed circuit board where the solder paste will be deposited, are extracted, special markers are located and identified on the captured pictures of the board, through pattern recognition methods, for the solder paste deposition, the position and orientation of the physical object to be targeted on the platform is identified, a donor substrate is placed and aligned, the donor is coated with a solder paste layer, digital solder deposition is achieved via laser printing, the printed circuit board to be assembled is placed in a component placement machine, the parts are deposited in predetermined positions and thermal annealing takes place for the final bonding.
2. Pattern recognition system for the assembly of printed circuit boards by digital printing, consisting of a pulsed laser source (1), an optical path (2), to guide the laser beam through a series of mirrors (11), a two-lens system setup, to magnify the laser beam to a size determined by the diameter of the entrance hole of the galvanometric system and to parallelize it, before entering the two-dimensional galvanometric system (8), an attenuating beam setup, of a controllable printing setup with a transparent carrier coated with solder paste (4-5), a receiver substrate (6), a stepper motor with movement in the Z direction and an adjustable XY translation stage configuration (7) and an imaging setup for real-time visualization, a CMOS camera (3), combined with an achromatic lens, a dichroic mirror, placed inline with the beam propagation axis (1), and a LED source illuminating the donor substrate (10).

1.-12. (canceled)

13. A method for assembling a printed circuit board using digital printing and pattern recognition, the method comprising:
fixing a printed circuit board onto a target platform;
adjusting a laser source with respect to the target platform;
capturing one or more images of the printed circuit board using an imaging system;
extracting coordinates of shapes and areas of interest on the printed circuit board from the captured images, the areas of interest being locations where solder paste is to be deposited;
locating and identifying one or more special colored markers on the printed circuit board using pattern recognition applied to the captured images;
determining a position and orientation of the printed circuit board on the target platform based on the identified markers;
placing a donor substrate on the target platform;
aligning the donor substrate with the printed circuit board;
coating the donor substrate with a solder paste layer;
depositing solder paste from the donor substrate onto the areas of interest on the printed circuit board via digital laser printing;
placing the printed circuit board in a component placement machine;
depositing one or more electronic components onto the printed circuit board at predetermined positions; and
performing thermal annealing to bond the solder paste and secure the electronic components to the printed circuit board.

14. The method of claim 13, wherein identifying of the special colored markers is performed against a black background, and wherein the method further comprises, when the background of the captured image is not black, the contrast of the image is adjusted to enhance visibility of the markers.

15. The method of claim 13, wherein identifying of the special markers includes converting the image to a black-and-white format such that the special markers are represented as white elements on a black background or as black elements on a white background.

16. The method of claim 15, further comprising counting the identified special markers in the converted image.

17. The method of claim 16, further comprising re-processing the set of identified elements, wherein each element is analyzed using a shape detection algorithm to determine whether the element matches a predefined geometric shape.

18. The method of claim 13, wherein the method further comprises evaluating edge pixels of each detected element to verify whether they satisfy certain criteria, such that the detected elements are classified into known shapes, and wherein the criteria are specific to the corresponding shape for which it is determined whether the detected element can be classified.

19. The method of claim 18, further comprising verifying whether each of the classified shapes belongs to a class of circular shapes.

20. The method of claim 19, further comprising presenting the detected circular shapes to a user for evaluation and acceptance.

21. The method of claim 13, wherein the method comprises identifying three special markers.

22. The method of claim 13, further comprising verifying that a required number of special markers has been identified, in particular prior to extracting the coordinates of the shapes and areas of interest on the printed circuit board where the solder paste is to be deposited.

23. The method of claim 13, wherein, for extracting the coordinates of the shapes and areas of interest on the printed circuit board where the solder paste is to be deposited, the method further comprises converting Gerber data of the printed circuit board into printing data, and wherein the method further comprises correcting errors related to the positions of the points to be printed and the orientation of the shapes to be printed.

24. A pattern recognition system for the assembly of printed circuit boards by digital printing, comprising:
a pulsed laser source;
an optical path configured to guide a laser beam through a series of mirrors;
a two-lens system configured to magnify the laser beam to a size determined by the diameter of an entrance hole of a two-dimensional galvanometric system and to parallelize the beam before entering the galvanometric system;
an attenuating beam setup, as part of a controllable printing setup comprising a transparent carrier coated with solder paste;
a receiver substrate;
a stepper motor configured for movement in the Z direction;
an adjustable XY translation stage configuration; and
an imaging setup for real-time visualization, comprising a CMOS camera, an achromatic lens, a dichroic mirror positioned along the beam propagation axis of the pulsed laser source, and an LED source configured to illuminate a donor substrate;
wherein the imaging setup is configured to capture images of the printed circuit board to be assembled; and
wherein the pattern recognition system is configured to:
extract coordinates of the shapes and areas of interest on the printed circuit board where solder paste is to be deposited;
locate and identify special markers on the captured images of the board using pattern recognition methods; and
determine, for solder paste deposition, the position and orientation of the physical object to be targeted on a target platform used to fix the printed circuit board.
